(19) United States
(12) Patent Application Publication
(10) Pub. No.: US 2004/0022296 A1
(43) Pub. Date: Feb. 5, 2004

(54) Laser containment structure allowing the use of plastics

(76) Inventors: Yefim P. Sukhman, Scottsdale, AZ (US); Christian J. Risser, Scottsdale, AZ (US); Edwin W. Gorham, Phoenix, AZ (US); Stefano J. Noto, Mesa, AZ (US); Cory W. Worth, Phoenix, AZ (US); David J. Aitchison, Gilbert, AZ (US)

Correspondence Address: ABELMAN, FRAYNE & SCHWAB, 150 East 42nd Street, New York, NY, 10017-5612, US

(21) Appl. No.: 10/210,121

(22) Filed: Jul. 31, 2002

(51) Int. Cl. B32B 1/02; H01S 3/00; H01S 5/022; B05D 7/22; B32B 1/10

(52) U.S. Cl. 372/109; 428/35.7; 156/214; 156/222; 427/376.7; 427/230

(57) ABSTRACT

A laser safety enclosure structure has an outer enclosure made of a formable material with a limited ability to withstand exposure to a laser beam and an inner enclosure composed of a laser beam blocking material capable of indefinitely withstanding exposure to a laser beam of a given wavelength and power level so as to prevent such a laser beam incident on the blocking material from escaping the inner enclosure.

### FIELD OF THE INVENTION

This invention relates to laser material processing systems, and in particular relates to a laser enclosure for safely containing the laser source of such systems.

### BACKGROUND OF THE INVENTION

Material processing systems using high power lasers must be housed in enclosures which contain the laser beam and prevent human exposure to laser radiation in excess of safe limits. This is not only good design practice, but is also required by both federal and state regulations as overseen by the Center for Devices and Radiological Health (CDRH), a division of the FDA. According to federal regulations:

21CFR1J-1040.10(f)(1) Performance Requirements—Protective Housing.

Each laser product shall have a protective housing that prevents human access during operation to laser and collateral radiation that exceed the limits of Class I and table IV, respectively, wherever and whenever such human access is not necessary for the product to perform its intended function.

To provide a Class I enclosure, the materials employed in the housing must be able to withstand indefinitely direct exposure to the beam of the laser in use in the system.

Common practice is to use sheet metal as the housing material to meet these requirements. However, sheet metal has the following drawbacks:

1) Sheet metal manufacturing methods can be relatively expensive, especially for mass production.

2) Low volume sheet metal manufacturing methods do not allow a wide range of shapes for the enclosures, which limits options for design aesthetics.

3) Stamping methods for sheet metal allow a wider range of shapes, but require expensive upfront tooling costs and are usually reserved for high volume manufacturing.

Plastics solve many of these problems, reducing material, tooling and manufacturing costs and allowing a much wider range of shapes. However, plastics do not meet safety guidelines because they cannot contain a beam indefinitely in the case of direct exposure to the laser beam.

An exception to the requirement of indefinite containment is the use of visibly transparent plastics as view ports, as long as the plastics are not transmissive to the laser wavelength in use. This is allowable if the material can prevent the laser beam from penetrating through for a reasonable period of time to allow the operator to recognize a problem and turn off the equipment while at the same time, by nature of its transparency to visible light, providing the operator a visual cue that a problem is occurring.

An example of this is the use of Acrylic plastic as a view port for systems employing CO₂ lasers operating at 10.6 microns. The Acrylic does not transmit this laser wavelength, but is transparent to visible light, allowing the operator to see whether the laser beam is striking the view port (or whether some other problem is occurring) before the beam burns through the view port, allowing the operator time to turn off the equipment before the enclosure is compromised.

Accordingly, manufacturers of laser material processing systems have conventionally used sheet metal enclosures to contain the laser beam and have employed clear glass or plastic only as viewing ports. As a result, since such systems are not usually built in large quantities, their enclosures have generally been restricted to square, boxy shapes.

### SUMMARY OF THE INVENTION

It is therefore an object of the present invention to provide a laser enclosure for a laser material processing system that avoids the above-described difficulties of the prior art.

It is a further object of the present invention to provide a laser enclosure for a laser material processing system that provides the required degree of safety while at the same time is able to be manufactured in any desired shape at a reasonable cost.

The above and other objects are achieved by the present invention which, in one embodiment, is directed to a laser safety enclosure structure with composite structure, comprising an outer enclosure having an interior surface, the outer enclosure being made of a formable material with a limited ability to withstand exposure to a laser beam, and an inner enclosure covering substantially all of the interior surface and defining an interior volume for containing a laser beam, the inner enclosure being composed of at least one layer of a laser beam blocking material capable of indefinitely withstanding exposure to a laser beam of a given wavelength and power level so as to prevent such a laser beam incident on the blocking material from escaping the inner enclosure.

In a preferred embodiment, the formable material is plastic and the blocking material is metal.

These and other objects, features and advantages of the present invention will be apparent from the following detailed description of the preferred embodiments taken in conjunction with the following drawings, wherein like reference numerals denote like elements.

### BRIEF DESCRIPTION OF THE DRAWINGS

FIG. 1 is a cross-sectional view of a wall portion of a laser safety enclosure in accordance with a first preferred embodiment of the present invention.

FIG. 2 is a cross-sectional view of a wall portion of a laser safety enclosure in accordance with a second preferred embodiment of the present invention.

FIG. 3 is a cross-sectional view of a wall portion of a laser safety enclosure in accordance with a third preferred embodiment of the present invention.

FIG. 4 is a cross-sectional view of a wall portion of a laser safety enclosure in accordance with a fourth preferred embodiment of the present invention.

FIG. 5 is a cross-sectional view of a wall portion of a laser safety enclosure in accordance with a fifth preferred embodiment of the present invention.

FIG. 6 is a cross-sectional view of a wall portion of a laser safety enclosure in accordance with a sixth preferred embodiment of the present invention.

### DETAILED DESCRIPTION OF THE PREFERRED EMBODIMENTS

The present invention is generally directed to a composite structure for a laser safety enclosure in which the exterior material of an outer enclosure is selected for low cost and ease of manufacturing and the ability to be formed into more complex, curved, homogeneous shapes with greater aesthetic appeal and without regard to the ability of the exterior material to block and contain the laser beam. As used in the present application, a material having this ability to be formed into such shapes is termed a formable material, a primary example being plastic.

The use of this exterior material is combined with the use of an interior material to make an inner enclosure, the inner material being selected for its ability to block and contain the laser beam. A primary example of a suitable inner material would be metal.

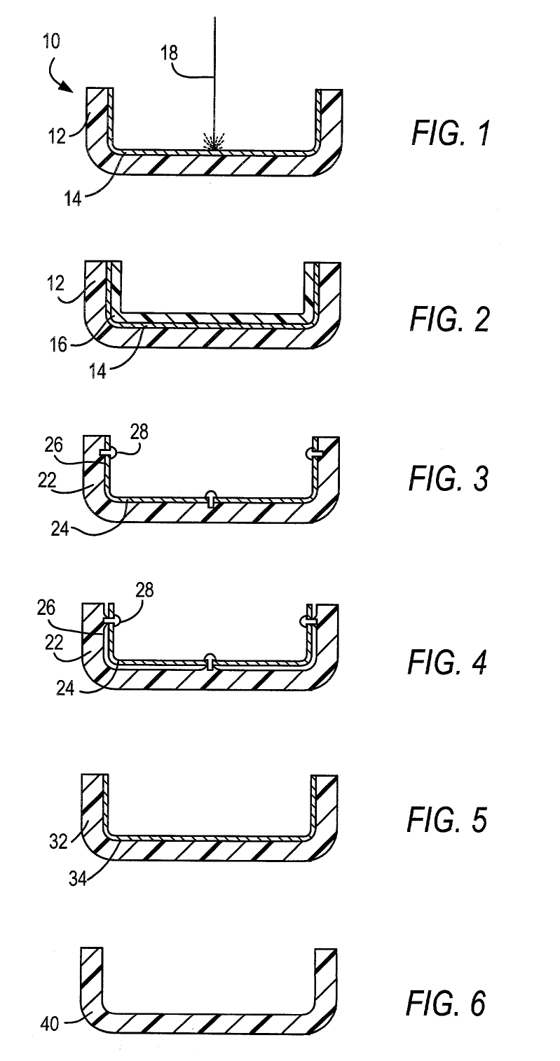

FIG. 1 is a cross-sectional view of a wall portion 10 of a laser safety enclosure in accordance with the present invention. It will be understood that substantially all of the walls of the laser safety enclosure will have the advantageous composite structure of the wall portion 10, with the possible exception of a viewing port or window that may be constructed in accordance with conventional techniques.

As shown in FIG. 1, the wall portion 10 consists of a first layer 12 of a suitable exterior material as defined above and a second layer 14 of a suitable interior material as defined above. In accordance with an advantageous aspect of the present invention, the first layer 12 is plastic and the second layer 14 is metal, advantageously aluminum. The wall portion 10 (and the rest of the laser safety enclosure) consisting of the first and second layers 12, 14 is created by applying a thin foil of aluminum to the inside of a sheet of plastic material using adhesive and then drawing the plastic and foil laminate into the appropriate shape using any suitable technique, for example vacuum forming techniques.

The foil must be of an appropriate thickness both to provide sufficient mechanical strength against tearing during the forming process and over the life of the enclosure, and to contain indefinitely a laser beam 18 of the intended wavelength and power level in order to meet the safety requirements. Experimental trials have indicated that the ranges of 0.010 to 0.015 inches thick for aluminum and 0.005 to 0.010 inches thick for copper meet both goals for unfocused CO₂ laser beams with power levels under 150 watts. It will be understood that an appropriate thickness of a suitable interior material appropriate for any specified laser wavelength and power level can be determined by one of ordinary skill in the art in accordance with the teachings of this specification.

When a viewing port or window is provided for viewing the interior volume of the laser safety enclosure from outside, the laser blocking material, which in this embodiment is the metal second layer 14, is absent from the window.

Other methods of constructing the wall portions of the laser safety enclosure are contemplated within the scope of the present invention. For example, in the embodiment shown in FIG. 2, a third layer 16 of plastic may be used, with the second layer 14 of metal between the first and third layers 12, 16. To create this structure, the foil could be laminated between two sheets of plastic and then formed into the appropriate shape using, e.g. vacuum forming techniques. This would provide an extra layer of protection for the foil to guard against ripping or tearing over the life of the product. It would also improve the cosmetics inside the equipment.

In another preferred embodiment shown in FIG. 3, a metal layer 24 can be made separately, for example by using the same type of vacuum forming technique employed for the plastic and metal laminate of the first and second embodiments or by stamping or other methods if quantities permitted. This allows the metal layer 24, advantageously aluminum foil, to be made in the appropriate shape to mate to the interior surface 26 of an injection molded or cast housing, such as plastic layer 22 (the outer enclosure). The metal layer 24 can be attached to the interior surface 26 of the plastic layer 22 using an adhesive or using mechanical fasteners 28, as shown in FIG. 3.

Alternatively, as shown in FIG. 4, the metal layer 24 can be spaced from the interior surface, with the mechanical fasteners 28 being attached to bosses 30 on the interior surface 26 of the plastic layer 22.

In another preferred embodiment shown in FIG. 5, the blocking material can be applied in the form of a metal powder that is sprayed or sintered to the interior surface 36 of a plastic housing 32 to form a metal layer 34 attached thereto with a sufficient thickness for laser beam confinement.

In yet another preferred embodiment, the metal powder can be mixed into a plastic resin to create a formable composite material having the appropriate heat dissipation and laser beam containment characteristics. The composite material can thereafter be formed into a wall portion 40 of the laser safety enclosure.

The laser safety enclosure constructed in accordance with the present invention provides many advantages over the enclosures of the prior art. The invention allows the use of a wide range of plastic fabrication methods such as injection molding, casting and vacuum forming, which can provide significant cost savings over sheet metal techniques at various quantity levels.

The invention can also take advantage of relatively inexpensive materials, such as acrylic, polycarbonate, urethane and ABS for the exterior material and aluminum or copper for the interior material.

In addition, the invention allows for a much wider range of shapes for the enclosure of the laser product than does standard bending and welding of sheet metal, thus allowing for an improvement in aesthetics, functionality and overall product appeal to the consumer.

Use of the present invention also means that tooling costs for complex shapes are significantly less than those for stamping sheet metal, and plastic fabrication is much more suited to mass production than standard bending and welding of sheet metal.

While the disclosed method and structure have been particularly shown and described with respect to the preferred embodiments, it is understood by those skilled in the art that various modifications in form and detail may be made therein without departing from the scope and spirit of the invention. Accordingly, modifications such as those suggested above, but not limited thereto are to be considered within the scope of the invention, which is to be determined by reference to the appended claims.

I claim:

1. A laser safety enclosure structure with composite structure, comprising:
an outer enclosure having an interior surface, said outer enclosure being made of a formable material with a limited ability to withstand exposure to a laser beam; and
an inner enclosure covering substantially all of said interior surface and defining an interior volume for containing a laser beam, said inner enclosure being composed of at least one layer of a laser beam blocking material capable of indefinitely withstanding exposure to a laser beam of a given wavelength and power level so as to prevent such a laser beam incident on said blocking material from escaping said inner enclosure.

2. The structure of claim 1, wherein said inner enclosure comprises a first layer of laser beam blocking material connected to said interior surface.

3. The structure of claim 2, wherein said first layer of laser beam blocking material is laminated on said inner surface.

4. The structure of claim 2, wherein said first layer of laser beam blocking material is connected to said interior surface using an adhesive.

5. The structure of claim 2, wherein said first layer of laser beam blocking material is connected to said interior surface using at least one mechanical fastener.

6. The structure of claim 2, said inner enclosure further including a second layer of a formable material with a limited ability to withstand exposure to a laser beam, said first layer being sandwiched between said second layer and said interior surface of said outer enclosure.

7. The structure of claim 1, wherein a first layer of said at least one layer of laser beam blocking material is metal.

8. The structure of claim 1, wherein said layer of formable material is a plastic.

9. A method of making a laser safety enclosure with composite structure, comprising the steps of:
forming an outer enclosure of a formable material with limited ability to withstand exposure to a laser beam, the outer enclosure having an interior surface; and
making an inner enclosure of at least one layer of laser beam blocking material covering substantially all of the interior surface and defining an interior volume for containing a laser beam, the inner enclosure being composed of a material capable of withstanding indefinite exposure to a beam of a given wavelength and power level and preventing such a laser beam from escaping the inner enclosure.

10. The method of claim 9, wherein the outer and inner enclosures are made by the steps of:
providing a sheet of formable material presenting a first surface that will become the interior surface of the outer enclosure;
applying a first layer of beam blocking material to the first surface to form a laminate; and
drawing the laminate into shape to constitute the inner and outer enclosures.

11. The method of claim 10, wherein said applying step attaches the beam blocking material to the first surface using an adhesive.

12. The method of claim 9, wherein the at least one layer of laser beam blocking material is metal.

13. The method of claim 9, wherein the layer of formable material is plastic.

14. The method of claim 9, wherein at least one of said step of forming the inner enclosure and said step of forming the outer enclosure employs a technique selected from the group of vacuum forming techniques, injection molding techniques, casting techniques and stamping techniques.

15. The method of claim 9, wherein said step of forming the outer enclosure initially forms the outer enclosure as a separate entity, and said step of making the inner enclosure includes the step of attaching the beam blocking material to the interior surface of the formed outer enclosure to form the inner enclosure.

16. The method of claim 15, wherein said step of making the outer enclosure initially forms the inner enclosure as a separate entity, and said attaching step includes the step of connecting the made inner enclosure to the interior surface of the formed outer enclosure.

17. The method of claim 16, wherein the inner enclosure is made by stamping.

18. The method of claim 15, wherein said attaching step includes the step of applying the beam blocking material to the interior surface as a powder.

19. The method of claim 18, wherein the powder is a metal and is attached to the interior surface by a selected one of spraying and sintering.

20. A laser safety enclosure with composite structure, comprising an enclosure made from a plurality of walls and defining an interior volume for containing a laser beam, each of said walls being formed from a mixture of a moldable material and a beam blocking material in an amount sufficient to make said walls capable of withstanding indefinite exposure to a laser beam of a given wavelength and power level and preventing such a laser beam from escaping the enclosure.

21. The structure of claim 20, wherein the moldable material is a plastic resin.

22. The structure of claim 20, wherein the beam blocking material is a metal powder.

23. A method of making a laser safety enclosure with a composite structure, comprising the steps of:
making a mixture of moldable material and an amount of beam blocking material sufficient to make a wall formed of the mixture capable of withstanding indefinite exposure to a laser beam of a given wavelength and power level and preventing such a laser beam from escaping through the wall; and
making an enclosure having a wall formed of the mixture.

24. The method of claim 23, wherein the moldable material is a plastic resin.

25. The method of claim 23, wherein the beam blocking material is a metal powder.
